(19) United States
(12) Patent Application Publication
(10) Pub. No.: US 2022/0348713 A1
(43) Pub. Date: Nov. 3, 2022

(54) FILM AND LAMINATE FOR ELECTRONIC BOARD, AND ELECTRONIC BOARD COMPRISING SAME

(71) Applicant: SKC CO., LTD., Gyeonggi-do (KR)

(72) Inventors: Young Min HEO, Gyeonggi-do (KR); Ilho NOH, Gyeonggi-do (KR); Sang Mook KIM, Gyeonggi-do (KR); Byeong Jae LIM, Gyeonggi-do (KR)

(21) Appl. No.: 17/642,160

(22) PCT Filed: Sep. 24, 2020
(86) PCT No.: PCT/KR2020/012987

§ 371 Date: Mar. 10, 2022

(30) Foreign Application Priority Data
Oct. 2, 2019 (KR) 10-2019-0122080

(51) Int. Cl. C08G 63/199; C08J 5/18; H05K 1/03

(52) U.S. Cl. CPC C08G 63/199; C08J 5/18; H05K 1/0393; H05K 1/0326; C08J 2367/02

(57) ABSTRACT

A film for an electronic board, according to one embodiment, has a low dielectric constant of 2.9 or lower at a frequency of 10-40 GHz, and thus can cause the signal transmission rate for a high frequency use, such as fifth generation (5G) mobile communication, to be superior to that of a conventional film for an electronic board. In addition, the film for an electronic board has flexibility and physicochemical characteristics that are greater than or equal to those of a conventional film, so as to be applicable to the manufacture of a laminate of a conductive film such as FCCL and an electronic board such as a FPCB, thereby enabling processability, durability, transmission capacity and the like to be improved.

### TECHNICAL FIELD

Embodiments relate to a film and a laminate to be used in an electronic board such as a flexible printed circuit board (FPCB), and an electronic board comprising the same.

### BACKGROUND ART

In an electronic board such as a circuit board, which is an essential part of electronic devices, a conductive pattern is formed on an insulation substrate film. In particular, a flexible printed circuit board (FPCB) meets the recent trend of electronic is devices required to be thinner, lighter, and flexible.

In general, a flexible printed circuit board is manufactured by laminating a copper foil on one or both sides of a substrate film to prepare a flexible copper clad laminate (FCCL) and etching the copper foil thereof to form a conductive pattern.

In conventional electronic boards, polyimide (PI) films have been mainly used as a substrate film. In recent years, polyethylene naphthalate (PEN) films and liquid crystal polymer (LCP) films have also been actively used (see Korean Patent No. 1275159).

However, there have been difficulties in the use of the substrate film for such conventional electronic boards since it absorbs moisture under the conditions of high temperature and high humidity, resulting in a deterioration in the insulation of the film, it lacks thermal resistance, and its electrical properties such as dielectric constant with respect to temperature are not suitable, or it is rather expensive.

### DETAILED DESCRIPTION OF THE INVENTION

### Technical Problem

Accordingly, an object of the embodiments is to solve the problems of the substrate film used in the conventional electronic boards and to provide a film for an electronic board excellent in physical and chemical properties as well as electrical properties such as dielectric properties, and a laminate thereof with metals.

In addition, an object of the embodiments is to provide an electronic board with improved performance such as transmission capacity by using the above film or laminate for an electronic board.

### Solution to the Problem

According to an embodiment, there is provided a film for an electronic board, which comprises a polyester resin in which a diol comprising 1,4-cyclohexanedimethanol and an aromatic dicarboxylic acid are polymerized, wherein the film has a dielectric constant of 2.9 or less at a frequency of 10 GHz to 40 GHz.

According to another embodiment, there is provided a laminate for an electronic is board, which comprises a substrate layer and a conductive layer disposed on at least one side of the substrate layer, wherein the substrate layer comprises a polyester resin in which a diol comprising 1,4-cyclohexanedimethanol and an aromatic dicarboxylic acid are polymerized, and the substrate layer has a dielectric constant of 2.9 or less at a frequency of 10 GHz to 40 GHz.

According to still another embodiment, there is provided an electronic board, which comprises a substrate layer and a conductive pattern layer disposed on at least one side of the substrate layer, wherein the substrate layer comprises a polyester resin in which a diol comprising 1,4-cyclohexanedimethanol and an aromatic dicarboxylic acid are polymerized, and the substrate layer has a dielectric constant of 2.9 or less at a frequency of 10 GHz to 40 GHz.

### Advantageous Effects of the Invention

Since the film for an electronic board according to the embodiment has a low dielectric constant of 2.9 or less at a frequency of 10 GHz to 40 GHz, it is possible to enhance the signal transfer rate in high-frequency applications such as the fifth-generation (5G) mobile communication as compared with the conventional films for an electronic board.

In addition, since the film for an electronic board has characteristics equal to or higher than those of the conventional films in terms of flexibility and various physical and chemical properties, it can be applied to the manufacture of a laminate with a conductive layer such as FCCL and an electronic board such as FPCB, to thereby enhance the processability, durability, and transmission capacity.

### BRIEF DESCRIPTION OF THE DRAWING

FIG. 1 shows the dielectric constant of the film of Example 1 with respect to the frequency at room temperature.

### BEST MODE FOR CARRYING OUT THE INVENTION

In the following description of the embodiments, in the case where an element is mentioned to be formed “on” or “under” another element, it means not only that one element is directly formed “on” or “under” another element, but also that one element is indirectly formed on or under another element with other element(s) interposed between them.

Throughout the present specification, when a part is referred to as “comprising” an element, it is understood that other elements may be comprised, rather than other elements are excluded, unless specifically stated otherwise.

In addition, all numbers expressing the physical properties, dimensions, and the like of elements used herein are to be understood as being modified by the term “about” unless otherwise indicated.

[Film for an Electronic Board]

The film for an electronic board according to an embodiment comprises a polyester resin in which a diol comprising 1,4-cyclohexanedimethanol and an aromatic dicarboxylic acid are polymerized, wherein the film has a dielectric constant of 2.9 or less at a frequency of 10 GHz to 40 GHz.

Dielectric Constant

The dielectric constant is also called relative permittivity. In some cases, it is also referred to simply as permittivity. To be precise, the permittivity refers to the absolute value (F/m) standing for the effect of the medium between charges on the electric field when an electric field is applied between them. The dielectric constant refers to the ratio (εᵣ=ε/ε₀) of the permittivity (ε) of a material and the vacuum permittivity (ε₀) in which the vacuum permittivity is about 8.85×10⁻¹² F/m.

The numerical value of a dielectric constant described herein refers to a dielectric constant at room temperature, for example, 20° C. to 25° C., or about 20° C., unless otherwise stated.

The film for an electronic board according to an embodiment has a dielectric is constant of 2.9 or less at a frequency of 10 GHz to 40 GHz. Within the above range, it is possible to enhance the signal rate in a high-frequency range as compared with the conventional films for an electronic board.

Specifically, the dielectric constant of the film for an electronic board is 2.8 or less, 2.7 or less, 2.6 or less, 2.5 or less, 2.0 to 2.9, 2.0 to 2.8, 2.0 to 2.7, 2.0 to 2.6, 2.3 to 2.9, or 2.5 to 2.8, at a frequency of 10 GHz to 40 GHz.

According to another embodiment, the film for an electronic board has a dielectric constant of 2.9 or less at a frequency of 3 GHz to 10 GHz. According to still another embodiment, the film for an electronic board has a dielectric constant of 2.9 or less at a frequency of 3 GHz to 40 GHz.

Meanwhile, the dielectric constant of PI films mainly used as a substrate film for FPCB or FCCL usually exceeds 3.0 in the high-frequency region. Other PET films or PEN films used have a slightly lower dielectric constant than that of the PI films. Thus, it is possible for the film for an electronic board according to an embodiment to enhance the signal rate in the frequency range applicable to the fifth-generation (5G) mobile communication as compared with the conventional films.

In addition, the film for an electronic board according to an embodiment may have a dielectric constant of 2.9 or less at a frequency of 100 kHz and a temperature ranging from room temperature to 130° C. Within the above range, it is possible to enhance the signal rate in various external environmental conditions as compared with the conventional films for an electronic board.

Specifically, the dielectric constant of the film for an electronic board may be 2.9 or less, 2.8 or less, 2.7 or less, 2.6 or less, 2.5 or less, 2.0 to 2.8, 2.0 to 2.7, 2.0 to 2.6, 2.0 to 2.5, 2.3 to 2.8, or 2.5 to 2.8, at a frequency of 100 kHz and a temperature ranging from room temperature to 130° C.

In addition, the film for an electronic board may have a dielectric constant of 3.2 or less at a frequency of 100 kHz and a temperature of 130° C. to 200° C.

In addition, the film for an electronic board may have a dielectric constant of 2.9 or less at a frequency of 100 kHz and a temperature ranging from room temperature to is 200° C.

In addition, the film for an electronic board may have a deviation in the dielectric constant of 0.5 or less, 0.3 or less, 0.2 or less, 0.1 or less, or 0.05 or less, at a frequency of 100 kHz and a temperature ranging from room temperature to 130° C. Specifically, the film for an electronic board may have a deviation in the dielectric constant of 0.1 or less at a frequency of 100 kHz and a temperature ranging from room temperature to 100° C. The deviation in the dielectric constant refers to a difference between the maximum value and the minimum value of a dielectric constant within a certain temperature range.

In addition, the film for an electronic board may have a rate of increase in the dielectric constant of 1% to 15%, 2% to 9%, or 3% to 8%, at a frequency of 100 kHz and a temperature of 100° C. to 130° C. Specifically, the film for an electronic board may have a rate of increase in the dielectric constant of 2% to 9% at a frequency of 100 kHz and a temperature of 100° C. to 130° C. The rate of increase in the dielectric constant refers to a percentage of an increase in the final dielectric constant relative to the initial dielectric constant when the temperature is raised within a certain temperature range.

In addition, the film for an electronic board may have a deviation in the dielectric constant of 0.1 or more, 0.2 or more, 0.3 or more, 0.4 or more, 0.5 or more, 0.1 to 1, 0.3 to 1, or 0.4 to 0.7, at a frequency of 100 kHz and a temperature of 130° C. to 200° C. The deviation in the dielectric constant refers to a difference between the maximum value and the minimum value of a dielectric constant within a certain temperature range.

Meanwhile, the dielectric constants of PI films, PET films, and PEN films mainly used as a substrate film for FPCB or FCCL usually exceed 3.0 at a frequency of 100 kHz and a temperature ranging from room temperature to 200° C. Thus, it is possible for the film for an electronic board according to an embodiment to enhance the signal rate at not only room temperature but also high temperatures as compared with the conventional films.

The dielectric constant of the film for an electronic board according to an embodiment may be 3.1 or less, 3.0 or less, 2.9 or less, 2.0 to 3.1, 2.0 to 3.0, 2.0 to 2.95, 2.3 to 2.95, or 2.5 to 2.9, at a frequency of 10 GHz.

The dielectric constant of the film for an electronic board according to an embodiment may be 3.1 or less, 3.0 or less, 2.9 or less, 2.0 to 3.1, 2.0 to 3.0, 2.0 to 2.95, 2.3 to 2.95, or 2.5 to 2.9, at a frequency of 28 GHz.

The dielectric constant of the film for an electronic board according to an embodiment may be 3.1 or less, 3.0 or less, 2.9 or less, 2.0 to 3.1, 2.0 to 3.0, 2.0 to 2.95, 2.3 to 2.95, or 2.5 to 2.9, at a frequency of 50 GHz.

The dielectric constant of the film for an electronic board according to an embodiment may be 3.1 or less, 3.0 or less, 2.9 or less, 2.0 to 3.1, 2.0 to 3.0, 2.0 to 2.95, 2.3 to 2.95, or 2.5 to 2.9, at a frequency of 80 GHz.

Film Characteristics

The thickness of the film for an electronic board may be 1 μm to 500 μm, 5 μm to 250 μm, 10 μm to 150 μm, 10 μm to 100 μm, 10 μm to 80 μm, or 40 μm to 60 μm. As an example, the film for an electronic board may have a thickness of 10 μm to 150 μm.

The film for an electronic board is preferably a stretched film by virtue of its high crystallinity and excellent mechanical properties. Specifically, the film for an electronic board may be a biaxially stretched polyester film. For example, it may be a film stretched at a stretching ratio of 2.0 to 5.0 in the longitudinal direction (MD) and in the transverse direction (TD), respectively.

The film for an electronic board may have a glass transition temperature (Tg) of 80° C. to 110° C., 80° C. to 95° C., 85° C. to 105° C., or 90° C. to 105° C.

In addition, the film for an electronic board may have a melting temperature (Tm) of 255° C. to 290° C., 255° C. to 285° C., 250° C. to 280° C., or 255° C. to 280° C. The polyester resin contained in the film for an electronic board may have an intrinsic viscosity (IV) of 50% or more, 60% or more, 70% or more, 80% or more, 70% to 90%, or 75% to 85%, relative to the initial stage after treatment at 121° C. and 100% RH for 96 hours.

Specifically, the polyester resin may have an intrinsic viscosity (IV) of 70% to 90% relative to the initial stage after treatment at 121° C. and 100% RH for 96 hours. Within the above range, it is advantageous for preventing a deterioration in the film characteristics due to hydrolysis under the conditions of high temperature and high humidity.

In addition, the polyester resin may have an intrinsic viscosity (IV) of 0.6 dl/g to 0.9 dl/g, 0.65 dl/g to 0.85 dl/g, or 0.7 dl/g to 0.8 dl/g. In addition, the polyester resin may have an intrinsic viscosity (IV) of 0.5 dl/g to 0.8 dl/g, 0.6 dl/g to 0.7 dl/g, 0.5 dl/g to 0.6 dl/g, or 0.55 dl/g to 0.65 dl/g, after treatment at 121° C. and 100% RH for 96 hours.

The film for an electronic board may withstand 100 times or more, 1,000 times or more, 10,000 times or more, 50,000 times or more, 100,000 times or more, 150,000 times or more, or 200,000 times or more of repeated folding at an angle of 135° until it is broken. Within the above range, it can be advantageously applied to a flexible electronic device since it is not broken even upon frequent folding.

In addition, the film for an electronic board may have a moisture permeability of 10 g/m²·day to 100 g/m²·day, 10 g/m²·day to 50 g/m²·day, or 10 g/m²·day to 30 g/m²·day.

In addition, the film for an electronic board may have a transmittance of 10% or less, 5% or less, or 3% or less, at a wavelength of 380 nm. As an example, the film for an electronic board may have a moisture permeability of 10 g/m² day to 50 g/m² day and a transmittance of 5% or less at a wavelength of 380 nm.

The film for an electronic board may have a crystallinity of 35% to 55%. Within the above range, excessive crystallization can be prevented while excellent mechanical properties in terms of tensile strength and the like are secured. For example, the crystallinity of the film for an electronic board may be 35% to 50%, 40% to 55%, 35% to 50%, 45% to 55%, or 40% to 50%.

When a first direction and a second direction perpendicular to each other in a plane are defined, the film for an electronic board may have a ratio (s2/s1) of the thermal shrinkage rate (s2) in the second direction to the thermal shrinkage rate (s1) in the first direction of 1 to 5 under the conditions of 150° C. and 30 minutes. Specifically, the ratio (s2/s1) of the thermal shrinkage rates may be 1 to 4, 1 to 3, or 1.5 to 4.

In addition, the thermal shrinkage rate (s1) in the first direction may be 1% or less, 0.8% or less, 0.6% or less, or 0.4% or less. For example, the s1 may be 0% to 1.0%, 0% to 0.8%, 0% to 0.6%, or 0% to 0.4%. In addition, the thermal shrinkage rate (s2) in the second direction may be 3% or less, 2% or less, 1.5% or less, 1.2% or less, or 1% or less. For example, the s2 may be 0.2% to 3%, 0.2% to 2%, or 0.2% to 1.5%. As an example, the first direction may be the transverse direction (TD) of the film, and the second direction may be the longitudinal direction (MD) of the film Since the film for an electronic board has the above-described thermal shrinkage characteristics, lifting due to shrinkage does not occur under high-temperature conditions at the time of lamination with a conductive film, whereby it is possible to prevent a degradation in the performance caused by interlayer peeling-off.

Film Composition

The film for an electronic board comprises a polyester resin in which a diol and a dicarboxylic acid are polymerized. Such a polyester resin may be obtained by transesterification of the diol and the dicarboxylic acid and then polymerization thereof.

The diol comprises 1,4-cyclohexanedimethanol (CHDM). For example, it may comprise CHDM in an amount of 50% by mole or more, 70% by mole or more, 80% by mole or more, 85% by mole or more, 90% by mole or more, 95% by mole or more, or 98% by mole or more, based on the total number of moles of the diol. CHDM contained in the diol can lower the modulus of the polyester resin and also increase the glass transition temperature (Tg), thereby enhancing the thermal resistance and hydrolysis resistance. As an example, the diol comprises 1,4-cyclohexanedimethanol (CHDM) in an amount of 100% by mole.

The diol may further comprise a diol other than CHDM. That is, the polyester resin may be a copolymerized polyester resin.

Specific examples of the additional diol may include ethylene glycol, 1,3-propanediol, 1,2-octanediol, 1,3-octanediol, 2,3-butanediol, 1,3-butanediol, 1,4-butanediol, 1,5-pentanediol, 2,2-diethyl-1,3-propanediol (neopentyl glycol), 2-butyl-2-ethyl-1,3-propanediol, 2,2-diethyl-1,5-pentanediol, 2,4-diethyl-1,5-pentanediol, 3-methyl-1,5-pentanediol, 1,1-dimethyl-1,5-pentanediol, or a mixture thereof.

The dicarboxylic acid comprises one, two, or more types of an aromatic dicarboxylic acid.

For example, the aromatic dicarboxylic acid may comprise terephthalic acid, dimethyl terephthalic acid, or a combination thereof.

Specifically, the aromatic dicarboxylic acid may comprise terephthalic acid in an amount of 75% by mole to 97% by mole, specifically 80% by mole to 95% by mole, 82% by mole to 95% by mole, or 85% by mole to 95% by mole, based on the total number of moles of the aromatic dicarboxylic acid. Alternatively, the aromatic dicarboxylic acid may comprise terephthalic acid in an amount of 80% by mole or more or 90% by mole or more, specifically 80% by mole to less than 100% by mole, 90% by mole to less than 100% by mole, 93% by mole to less than 100% by mole, or 95% by mole to less than 100% by mole, based on the total number of moles of the aromatic dicarboxylic acid.

Accordingly, the polyester resin may comprise 1,4-cyclohexanedimethylene terephthalate as a repeat unit. Specifically, the polyester resin may comprise a poly(1,4-cyclohexylenedimethylene terephthalate) (PCT) resin.

The PCT resin is a crystalline polyester resin prepared by esterification or transesterification and polycondensation reaction of terephthalic acid (TPA) or dimethyl terephthalic acid (DMT) and 1,4-cyclohexanedimethanol (CHDM). It may have an excellent melting point (Tm) and crystallization characteristics. In addition, the PCT resin may have excellent thermal resistance, chemical resistance, moisture absorption resistance, and flowability as compared with such general-purpose polyesters as polyethylene terephthalate (PET) and polybutylene terephthalate (PBT). Since the film for an electronic board comprises a PCT resin, it may have increased crystallinity in the process of preparing the same through heating, stretching, and the like, and enhanced mechanical properties in terms of tensile strength and the like.

Meanwhile, if the crystallinity of the PCT resin is too high, undesired crystallization may occur when it is extruded for preparing a film or the film is stretched. Thus, the polyester resin may further comprise isophthalic acid as the aromatic dicarboxylic acid in order to lower the crystallization rate.

For example, the aromatic dicarboxylic acid may comprise isophthalic acid in an amount of 3% by mole to 25% by mole based on the total number of moles of the aromatic dicarboxylic acid. Specifically, the aromatic dicarboxylic acid may comprise isophthalic acid in an amount of 5% by mole to 20% by mole, 5% by mole to 18% by mole, or 5% by mole to 15% by mole, based on the total number of moles of the aromatic dicarboxylic acid. Alternatively, the aromatic dicarboxylic acid may comprise isophthalic acid in an amount of 10% by mole or less, specifically greater than 0% by mole to 7% by mole or greater than 0% by mole to 5% by mole, based on the total number of moles of the aromatic dicarboxylic acid. Within the above range, it is more advantageous for increasing the handling convenience of the polymer by lowering the melting temperature (Tm) of the polymer while reducing the crystallization rate that would otherwise be too high as CHDM is contained.

Accordingly, the polyester resin may comprise 1,4-cyclohexanedimethylene terephthalate and 1,4-cyclohexanedimethylene isophthalate as a repeat unit. Specifically, the polyester resin may comprise a poly(1,4-cyclohexylenedimethylene terephthalate-co-isophthalate) (PCTA) resin. In addition, the dicarboxylic acid may further comprise at least one selected from the group consisting of an aromatic dicarboxylic acid such as dimethylterephthalic acid, naphthalene dicarboxylic acid, orthophthalic acid, and the like; an aliphatic dicarboxylic acid such as adipic acid, azelaic acid, sebacic acid, decanedicarboxylic acid, and the like; an alicyclic dicarboxylic acid; and an ester thereof.

The film for an electronic board may comprise a polyester resin, specifically at least one of PCT and PCTA resins, in a total amount of 85% by weight or more, more specifically 90% by weight or more, 95% by weight or more, or 99% by weight or more, based on the weight of the film for an electronic board.

As another example, the film for an electronic board may further comprise a polyester resin other than the PCT or PCTA resin. Specifically, the film for an electronic board may further comprise about 15% by weight or less of a polyethylene terephthalate (PET) resin or a polyethylene naphthalate (PEN) resin based on the weight of the film for an electronic board. More specifically, the film for an electronic board may further comprise a PET or PEN resin in an amount of about 0.1% by weight to 10% by weight, or about 0.1% by weight to 5% by weight, based on the weight of the film for an electronic board.

The polyester resin may have a weight average molecular weight (Mw) of 30,000 g/mole to 50,000 g/mole or 30,000 g/mole to 40,000 g/mole.

Process for Preparing a Film for an Electronic Board

The process for preparing the film for an electronic board may comprise (1) extruding a composition comprising a polyester resin in which a diol comprising 1,4-cyclohexanedimethanol and a dicarboxylic acid are polymerized to form a sheet; (2) stretching the sheet in the longitudinal direction and the transverse direction; and (3) heat setting the stretched sheet.

In the above preparation process, the film for an electronic board is prepared by extruding a raw resin and subjecting it to preheating, stretching, and heat setting. In such event, the composition of the polyester resin used as a raw material of the film for an electronic board is as exemplified above. In addition, the composition and process conditions are adjusted such that the film finally produced by the above process satisfies the characteristics (the range of a dielectric constant) of the film for an electronic board according to the embodiment. Specifically, in order for the final film to satisfy the above characteristics, the extrusion and casting temperatures of the polyester resin are adjusted, the preheating temperature at the time of stretching, the stretching ratio in each direction, the stretching temperature, the transferring speed, and the like are adjusted, or thermal treatment and relaxation are carried out after the stretching while the thermal treatment temperature and relaxation rate are adjusted.

Hereinafter, exemplary process conditions are described, but they are not limited thereto.

The polyester resin may be dried before extrusion. The drying temperature here is preferably 150° C. or less to prevent discoloration. The extrusion may be carried out at a temperature of 230° C. to 300° C. or 250° C. to 290° C.

The film for an electronic board is preheated at a certain temperature before stretching thereof. The preheating temperature may be determined to satisfy the range of Tg+5° C. to Tg+50° C. based on the glass transition temperature (Tg) of the polyester resin. For example, it may be in the range of 70° C. to 90° C. Within the above range, the film for an electronic board may be soft enough to be readily stretched, and it is possible to effectively prevent the phenomenon of breakage during stretching thereof as well.

The stretching is carried out by biaxial stretching. For example, it may be biaxially stretched in the longitudinal direction (or machine direction; MD) and in the transverse direction (or tenter direction; TD) through a simultaneous biaxial stretching method or a sequential biaxial stretching method. Preferably, it may be carried out by a sequential biaxial stretching method in which stretching is first performed in one direction and then stretching is performed in the direction perpendicular thereto.

The stretching ratio in the longitudinal direction may be in a range of 2.0 to 5.0, more specifically 2.8 to 3.5. In addition, the stretching ratio in the transverse direction may be in a range of 2.0 to 5.0, more specifically 2.9 to 3.7. Preferably, the stretching ratio in the longitudinal direction and the stretching ratio in the transverse direction are similar to each other. Specifically, the ratio (d2/d1) of the stretching ratio (d2) in the longitudinal direction to the stretching ratio (dl) in the transverse direction may be 0.5 to 1.0, 0.7 to 1.0, or 0.9 to 1.0. The stretching ratios (d1 and d2) refer to the ratios that represent the length after stretching as compared with the length before stretching being 1.0. In addition, the stretching speed may be 6.5 m/min to 8.5 m/min, but it is not particularly limited thereto.

The stretched sheet may be heat set at 150° C. to 250° C., more specifically 200° C. to 250° C. The heat setting may be carried out for 5 seconds to 1 minute, more specifically for 10 seconds to 45 minutes.

After the heat setting is initiated, the sheet may be relaxed in the longitudinal direction and/or in the transverse direction, and the temperature range therefor may be 150° C. to 250° C. The relaxation rate may be 1% to 10% or 3% to 7%.

Since the film for an electronic board according to an embodiment is excellent in dielectric characteristics and has characteristics equal to or higher than those of the conventional films in terms of flexibility and various physical and chemical properties, it can be applied to the manufacture of a laminate with a conductive film such as FCCL and an electronic board such as FPCB, to thereby enhance the processability, durability, and transmission capacity.

[Laminate for Electronic Board]

The laminate for an electronic board according to an embodiment comprises a substrate layer and a conductive layer disposed on at least one side of the substrate layer, wherein the substrate layer comprises a polyester resin in which a diol comprising 1,4-cyclohexanedimethanol and an aromatic dicarboxylic acid are polymerized, and the substrate layer has a dielectric constant of 2.9 or less at a frequency of 10 GHz to 40 GHz.

The laminate for an electronic board may comprise a copper clad laminate (CCL), specifically a flexible copper clad laminate (FCCL).

Substrate Layer

The substrate layer may have substantially the same characteristics and composition as those of the film for an electronic board according to an embodiment as described above.

Conductive Layer

The conductive layer may comprise a conductive material. For example, the conductive layer may comprise a conductive metal. Specifically, the conductive layer may be a metal foil. For example, the conductive layer may comprise at least one metal selected from the group consisting of copper, nickel, gold, silver, zinc, and tin. More specifically, the conductive layer may be a copper foil.

The conductive layer may have a thickness of 6 μm to 200 μm, specifically 10 μm to 150 μm, 10 μm to 100 μm, or 20 μm to 50 μm.

Adhesive Layer

The laminate for an electronic board may further comprise an adhesive layer to increase the adhesion between the components. For example, an adhesive layer may be interposed between the substrate layer and the conductive layer.

The adhesive layer may comprise a thermosetting resin, for example, an epoxy-based resin. Examples of the epoxy resin include bisphenol-type epoxy resins; spiro-cyclic based epoxy resins; naphthalene-type epoxy resins; biphenyl-type epoxy resins; terpene-type epoxy resins; glycidyl ether-type epoxy resins; glycidyl amine-type epoxy resins; and novolac-type epoxy resins.

The epoxy-based resin may have an epoxy equivalent weight of about 80 g/eq. to 1,000 g/eq. or about 100 g/eq. to 300 g/eq. In addition, the epoxy-based resin may have a number average molecular weight in the range of about 10,000 g/mole to 50,000 g/mole.

The adhesive layer may have a thickness of 1 μm to 50 μm. More specifically, the adhesive layer may have a thickness of 10 μm to 50 μm or 20 μm to 40 μm.

Via

The laminate for an electronic board may further comprise a via for electrically connecting the conductive layers while penetrating the substrate layer in the thickness direction.

Specifically, the laminate for an electronic board comprises a hole penetrating the substrate layer in the thickness direction, and a via is formed inside the hole to electrically connect the conductive layers laminated on both sides of the substrate layer.

The hole may have a diameter, for example, in the range of 100 μm to 300 μm or 120 μm to 170 μm.

If necessary, a plurality of holes may be present in the laminate.

The via may comprise a conductive material. For example, the via may comprise at least one metal selected from the group consisting of copper, nickel, gold, silver, zinc, and tin.

The via may be formed by filling the hole with a conductive material, inserting a solder or a conductive rod, or plating.

[Electronic Board]

The electronic board according to an embodiment comprises a substrate layer and a conductive pattern layer disposed on at least one side of the substrate layer, wherein the substrate layer comprises a polyester resin in which a diol comprising 1,4-cyclohexanedimethanol and an aromatic dicarboxylic acid are polymerized, and the substrate layer has a dielectric constant of 2.9 or less at a frequency of 10 GHz to 40 GHz.

The electronic board may comprise a printed circuit board (PCB), specifically a flexible printed circuit board (FPCB).

Substrate Layer

The substrate layer may have substantially the same characteristics and composition as those of the film for an electronic board according to an embodiment as described above.

Conductive Pattern Layer

The conductive pattern layer comprises at least one conductive pattern.

The conductive pattern may comprise a conductive material. For example, the conductive pattern may comprise a conductive metal. Specifically, the conductive pattern may comprise at least one metal selected from the group consisting of copper, nickel, gold, silver, zinc, and tin. More specifically, the conductive pattern may comprise a copper foil.

The shape of the conductive pattern is not particularly limited. For example, it may comprise a line pattern or a flat spiral pattern.

In addition, the conductive pattern layer may comprise a circuit pattern. More specifically, the conductive pattern layer may comprise a printed circuit pattern.

In addition, the conductive pattern layer may comprise a terminal pattern. The terminal pattern may be electrically connected to an external circuit.

Adhesive Layer

In addition, the electronic board may further comprise an adhesive layer to increase the adhesion between the components. For example, an adhesive layer may be interposed between the substrate layer and the conductive pattern layer.

The composition and characteristics of the adhesive layer may be the same as those of the adhesive layer in the laminate for an electronic board as described above.

Via

In addition, the electronic board may further comprise a via for electrically connecting the conductive patterns while penetrating the substrate layer in the thickness direction.

The composition and characteristics of the via may be the same as those of the via in the laminate for an electronic board as described above.

### Embodiments for Carrying Out the Invention

Hereinafter, the present invention will be described more specifically with reference to examples. But the scope of the present invention is not limited thereto only.

### EXAMPLE

### Preparation Example: Resin A

A stirrer was charged with 100% by mole of 1,4-cyclohexanedimethanol (CHDM) as a diol, 5% by mole of isophthalic acid (IPA) and 95% by mole of terephthalic acid (TPA) as a dicarboxylic acid, and 0.001% by weight of Ti as a reaction catalyst was added thereto, followed by a transesterification reaction at 275° C. Upon completion of the transesterification reaction, the reaction product was transferred to a separate reactor equipped with a vacuum apparatus and then polymerized at 285° C. for 160 minutes to obtain Resin A.

### Preparation Example: Resins B to E

The procedure of Preparation Example of Resin A was repeated, except that the types and amounts of the diol and dicarboxylic acid monomers were changed as shown in Table 1 to prepare Resins B to E, respectively.

TABLE 1

| | Diol (% by mole) | | Dicarboxylic acid (% by mole) | | |
|---|---|---|---|---|---|
| | EG | CHDM | NDC | TPA | IPA |
| Resin A | — | 100 | — | 95 | 5 |
| Resin B | — | 100 | — | 90 | 10 |
| Resin C | — | 100 | — | 85 | 15 |
| Resin D | 100 | — | — | 100 | — |
| Resin E | 100 | | 100 | — | — |

*NDC: dimethyl-2,6-naphthalene dicarboxylate

### Examples 1 to 3 and Comparative Examples 1 and 2: Preparation of a Polyester Film

The resin prepared above was dried at a temperature of 150° C. or lower, extruded at about 280° C. with an extruder, and cast at about 20° C. with a casting roll to form a sheet. The sheet was preheated, followed by stretching thereof in the longitudinal direction (MD) and the transverse direction (TD) at a temperature of 110° C. Thereafter, the stretched sheet was heat set for about 30 seconds and relaxed to prepare a polyester film, respectively. The resins and process conditions adopted in the production of a film are summarized in Table 2 below.

TABLE 2

| | Raw | | | | Heat | Relaxation |
|---|---|---|---|---|---|---|
| | material | Stretching ratio | | R/H | setting | rate |
| | resin | MD | TD | (° C.) | (° C.) | (%) |
| Ex. 1 | Resin A | 2.9 | 3.7 | 750 | 240 | 5 |
| Ex. 2 | Resin B | 2.95 | 3.7 | 750 | 240 | 5 |
| Ex. 3 | Resin C | 3 | 3.75 | 750 | 240 | 5 |
| C. Ex. 1 | Resin D | 3 | 3.8 | 750 | 240 | 5 |
| C. Ex. 2 | Resin E | 3.1 | 3.8 | 750 | 240 | 5 |

### Comparative Example 3

A polyimide (PI) film of 50 μm in thickness commercially available from SKC Kolon PI was used.

Dielectric Constant

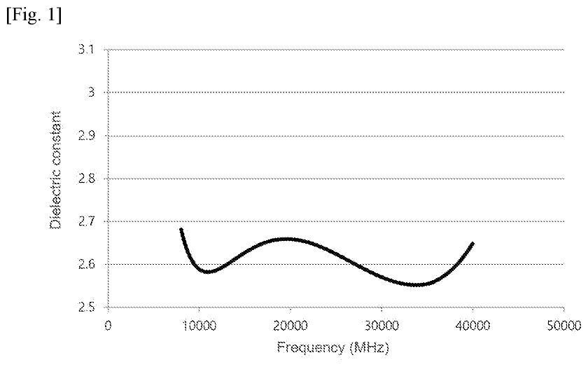

First, the dielectric constant of the film of Example 1 was measured using a dielectric test kit (Dielectric Assessment Kit, DAK-TL, SPEAG), and it is shown in Table 3 below and FIG. 1. FIG. 1 shows the dielectric constant of the film of Example 1 with respect to the frequency at room temperature.

In addition, the dielectric constants of the films of Example 1 and Comparative Examples 1 to 3 with respect to temperature at 100 kHz were measured using DETA (DS6010) equipment of Triton Technology Ltd., and they are shown in Table 4 below.

In addition, the dielectric constants of the films of Examples 2 and 3 and Comparative Examples 1 to 3 were measured at 10 GHz, 28 GHz, 50 GHz, and 80 GHz using measurement equipment of a resonance method from Keysight, and they are shown in Table 5 below.

TABLE 3

| | Dielectric constant (room temp.) |
|---|---|
| Frequency | Example 1 |
| 10 GHz | 2.59 |
| 15 GHz | 2.63 |
| 20 GHz | 2.66 |
| 25 GHz | 2.62 |
| 28 GHz | 2.59 |
| 30 GHz | 2.57 |
| 35 GHz | 2.55 |
| 40 GHz | 2.65 |

TABLE 4

| | Dielectric constant (100 kHz) | | | |
|---|---|---|---|---|
| Temp. (° C.) | Ex. 1 | C. Ex. 1 | C. Ex. 2 | C. Ex. 3 |
| 25.7 | 2.62 | 2.86 | 2.82 | 3.05 |
| 50.2 | 2.64 | 2.89 | 2.82 | 3.03 |
| 75.4 | 2.64 | 2.90 | 2.82 | 2.98 |
| 100.5 | 2.63 | 2.91 | 2.80 | 2.90 |
| 125.7 | 2.72 | 3.00 | 2.78 | 2.85 |
| 149.5 | 2.74 | 3.12 | 2.82 | 2.82 |
| 175.1 | 2.99 | 3.16 | 2.91 | 2.81 |
| 200.5 | 2.71 | 2.80 | 2.96 | 2.79 |

TABLE 5

| | Dielectric constant (room temp.) | | | | |
|---|---|---|---|---|---|
| Frequency | Ex. 2 | Ex. 3 | C. Ex. 1 | C. Ex. 2 | C. Ex. 3 |
| 10 GHz | 2.84 | 2.82 | 3.17 | 3.26 | 3.37 |
| 28 GHz | 2.87 | 2.83 | 3.17 | 3.24 | 3.37 |
| 50 GHz | 2.84 | 2.81 | 3.15 | 3.21 | 3.33 |
| 80 GHz | 2.85 | 2.80 | 3.13 | 3.20 | 3.33 |

As shown in Tables 3 to 5 above and FIG. 1, the films of Examples 1 to 3 had low dielectric constants in the high-frequency region in which signal rate is excellent, such as the 5G mobile communication, as compared with the films of Comparative Examples 1 to 3. Thus, they are suitable for use as a film for a circuit board. In addition, as shown in Table 4, the film of Example 1 had a low dielectric constant under various temperature conditions as compared with the films of Comparative Examples 1 to 3. Thus, it is possible to prevent a degradation in the performance at high temperatures.

Glass Transition Temperature (Tg)

The glass transition temperature (Tg) of the film sample was measured using a differential scanning calorimeter (DSC, Q2000, TA Instrument). The results are shown in Table 6 below.

Thermal Shrinkage Rate (%)

The film sample was cut into 20 mm×150 mm and thermally treated in an oven at 150° C. for 30 minutes. The thermal shrinkage rate (%) was measured for each of the longitudinal direction (MD) and the transverse direction (TD) before and after the thermal treatment. The results are shown in Table 6 below.

Intrinsic Viscosity (IV)

The intrinsic viscosity (IV) of the film sample was measured. In addition, the intrinsic viscosity (IV) was measured after it was treated for 96 hours at 121° C. and 100% RH in a high-temperature and high-pressure cooker. The results are shown in Table 6 below.

TABLE 6

| | | | | | | Thermal shrinkage | |
|---|---|---|---|---|---|---|---|
| | Thickness (μm) | Tg | Tm | IV (dl/g) | | rate (%) | |
| | (μm) | (° C.) | (° C.) | 0 hr | 96 hr | MD | TD |
| Ex. 1 | 50 | 93 | 280 | 0.673 | 0.589 | 0.5 | 0.2 |
| Ex. 2 | 50 | 91 | 269 | 0.681 | 0.564 | 0.98 | 0.35 |
| Ex. 3 | 50 | 90 | 261 | 0.702 | 0.591 | 0.4 | 0.1 |
| C. Ex. 1 | 50 | 78 | 250 | 0.591 | 0.348 | 1.1 | 0.3 |
| C. Ex. 2 | 50 | 122 | 266 | 0.623 | 0.541 | 0.4 | 0.25 |
| C. Ex. 3 | 50 | 216 | — | — | — | 0.1 | 0.1 |

As shown in Table 6 above, the film prepared in the Examples had very little change in viscosity even under the conditions of high temperature and high humidity as compared with the films of Comparative Examples, and other properties were excellent as well.

1. A film for an electronic board, which comprises a polyester resin in which a diol comprising 1,4-cyclohexanedimethanol and an aromatic dicarboxylic acid are polymerized, wherein the film has a dielectric constant of 2.9 or less at a frequency of 10 GHz to 40 GHz.

2. The film for an electronic board of claim 1, which has a dielectric constant of 2.9 or less at a frequency of 100 kHz and a temperature ranging from room temperature to 130° C. and a dielectric constant of 2.9 or less at a frequency of 3 GHz to 10 GHz.

3. The film for an electronic board of claim 2, which has:
a deviation in the dielectric constant of 0.1 or less at a frequency of 100 kHz and a temperature ranging from room temperature to 100° C.,
a rate of increase in the dielectric constant of 2% to 9% at a frequency of 100 kHz and a temperature of 100° C. to 130° C., and
a deviation in the dielectric constant of 0.2 or more at a frequency of 100 kHz and a temperature of 130° C. to 200° C.

4. The film for an electronic board of claim 1, wherein the aromatic dicarboxylic acid comprises isophthalic acid in an amount of 3% by mole to 25% by mole based on the total number of moles of the aromatic dicarboxylic acid, and the polyester resin has an intrinsic viscosity (IV) of 70% to 90% relative to the initial stage after treatment at 121° C. and 100% RH for 96 hours.

5. The film for an electronic board of claim 1, which withstands 100 times or more of repeated folding at an angle of 135° until the film is broken and which has a crystallinity of 35% to 55%.

6. The film for an electronic board of claim 1, wherein, when a first direction and a second direction perpendicular to each other in a plane are defined, the film for an electronic board has a thermal shrinkage rate (s1) in the first direction of 1% or less, a thermal shrinkage rate (s2) in the second direction of 3% or less, and a ratio (s2/s1) of the thermal shrinkage rate (s2) in the second direction to the thermal shrinkage rate (s1) in the first direction of 1 to 5, under the conditions of 150° C. and 30 minutes.

7. A laminate for an electronic board, which comprises a substrate layer and a conductive layer disposed on at least one side of the substrate layer, wherein the substrate layer comprises a polyester resin in which a diol comprising 1,4-cyclohexanedimethanol and an aromatic dicarboxylic acid are polymerized, and the substrate layer has a dielectric constant of 2.9 or less at a frequency of 10 GHz to 40 GHz.

8. The laminate for an electronic board of claim 7, which comprises a flexible copper clad laminate (FCCL).

9. An electronic board, which comprises a substrate layer and a conductive pattern layer disposed on at least one side of the substrate layer, wherein the substrate layer comprises a polyester resin in which a diol comprising 1,4-cyclohexanedimethanol and an aromatic dicarboxylic acid are polymerized, and the substrate layer has a dielectric constant of 2.9 or less at a frequency of 10 GHz to 40 GHz.

10. The electronic board of claim 9, which comprises a flexible printed circuit board (FPCB).
